(19) United States
(12) Patent Application Publication
(10) Pub. No.: US 2026/0078965 A1
(43) Pub. Date: Mar. 19, 2026

(54) HEAT SINK

(71) Applicants: ElringKlinger Automotive Manufacturing Inc., Southfield, MI (US); ElringKlinger AG, Dettingen/Erms (DE)

(72) Inventors: Thomas Friedow, Plymouth, MI (US); Thomas Soard, Southfield, MI (US); James Hess, Southfield, MI (US); Gunnar Schaefer, Southfield, MI (US)

(21) Appl. No.: 19/105,965

(22) PCT Filed: Aug. 22, 2023
(86) PCT No.: PCT/EP2023/073071

§ 371 Date: Feb. 24, 2025

Related U.S. Application Data
(60) Provisional application No. 63/399,948, filed on Aug. 22, 2022.

(30) Foreign Application Priority Data
Sep. 16, 2022 (DE) 10 2022 123 868.7

(51) Int. Cl. F28F 3/08; F28F 21/08; H05K 7/20

(52) U.S. Cl. CPC F28F 3/08; F28F 21/084; H05K 7/20409

(57) ABSTRACT

A heat sink on a closed housing of an electronic component or circuit. In order to produce a heat sink for an electronic component or circuit on a closed housing, it is proposed for a cooling element with a good thermal coupling to be positioned on a back side of the electronic component or circuit wherein the cooling element comprises at least one first metal plate with a three-dimensional structure, heat is introduced via a flat base of the first metal plate and heat is conveyed away toward apexes of the three-dimensional structure, wherein at least one second metal plate is positioned so that it adjoins the first metal plate or the apexes thereof with thermal contact in order to convey away the heat.

### FIELD OF THE INVENTION

The present invention relates to a heat sink on a closed housing of an electronic component or circuit.

### BACKGROUND OF THE INVENTION

Various approaches are known from the prior the art for dissipating heat, which is generated as thermal power loss in electrical components. Particularly in closed housings, this can lead to the formation of hot spots, which in the case of electronic components can have a very negative impact on reliable continuous operation due to a rapid increase in the probability of failure associated with the temperature. To prevent premature failure of electronic components, the prior art provides redundant units, among other things. Alternatively, the electrical components used are deliberately oversized in order to take into account the higher temperatures in the event of high loads and to achieve a sufficient service life overall. The above-mentioned design approaches, however, require more space and entail additional costs, if they can be achieved at all in the generally confined conditions in a closed housing. A reduced service life of electronic components also leads to increased costs and reduced reliability and can therefore not be seriously considered as a solution.

DE 10 2019 120 031 A1 discloses an integrated heat sink system that uses free and/or forced convection in a high-voltage interconnection box of a battery storage system to equalize the thermal conditions across an entire circuit with various electronic components. Such a heat sink system has proven its value, but in principle can only be used in closed housings in which it is possible to build up a convective flow.

Active cooling systems are known for large-area circuits in a closed housing, e.g. for solar modules. In these systems, a liquid, a gas, or a gas mixture such as air must be pumped through the housing to cool the solar module. But such active cooling systems are expensive and require additional installation space and electrical energy. In addition, such cooling systems wear out and, as actively driven sub-systems, can also fail directly due to internal defects or indirectly due to an interruption in the power supply.

The object of the present invention is to produce a heat sink for an electronic component or circuit on a closed housing, wherein the heat sink can also be part of the closed housing.

### SUMMARY OF THE INVENTION

This object is attained according to the invention by means of the features of claim 1 by means of heat sink on a closed housing of an electronic component or circuit, which has a cooling element with a good thermal coupling positioned on a back side of the electronic component or circuit, in order to convey heat away so as to increase a service life and/or an efficiency of the component or circuit. The cooling element comprises at least one first metal plate with a three-dimensional structure. Heat is introduced via a flat base and is conveyed away toward the apexes of the three-dimensional structure, where at least one second metal plate is positioned so that it adjoins the first metal plate or more specifically the apexes thereof with thermal contact and in this way, conveys away an absorbed heat.

Advantageous modifications are the subject of the dependent claims. According to these dependent claims, the metal plate is embodied as an aluminum sheet with a profiling in the form of a stamped three-dimensional structure. Aluminum is a good heat conductor that is inexpensive and corrosion-resistant. A three-dimensional structure can be easily produced in the comparatively soft aluminum by means of stamping, in particular also by means of a roll-stamping process using aluminum strip material, in which, in addition to a profiling of the aluminum sheet, a cutting to produce a metal plate with a precise final contour is also simultaneously carried out in a continuous manufacturing process.

Preferably, the three-dimensional structure of the metal plate is embodied in an optimized way to support high static and dynamic mechanical loads. This will be discussed in greater detail based on an exemplary embodiment.

In a modification of the invention, the three-dimensional structure is embodied as a regular structure. Preferably, a bead or nub structure is provided, wherein raised regions are molded so that they protrude from a flat bottom side or base.

In an advantageous modification of the invention, the second metal plate likewise has a three-dimensional profile. In particular, the second metal plate is provided with the same three-dimensional structure as the first metal plate.

Preferably, a heat sink according to the invention is embodied and shaped in such a way that the base of the first metal plate and that of the second metal plate, respectively, are oriented facing in opposite directions from each other.

In a preferred modification of the invention, a mirror-image arrangement of the first metal plate and the second metal plate with respect to each other is provided, with both having the same profiling. When the metal plates have the above-mentioned same three-dimensional structure and mirror-image arrangement, the respective apexes adjoin one another so that the heat is conveyed from apex to apex.

Advantageously, at least one first metal plate and at least one second metal plate are stacked on top of each other. With sufficient contact of the components to one another, the transmission of heat does not require the sheets to be secured to one another. Thus, in one embodiment of the invention, the result is a stack of several metal plates stacked in mirror-image orientation to one another, which are not secured to one another.

In a preferred embodiment of the invention, recessed regions are provided at the edges of the metal plates in order to secure the heat sink in an external frame; in particular, these recessed regions are provided only on a respective bottom and top sheet metal plate.

In a modification of the invention, a stack composed of three packets of first metal plates and second metal plates arranged in pairs is provided, which, preferably on the side of the stack of metal plates opposite from the closed housing of the electronic component or circuit, dissipates heat into a supporting surface by means of a rod. For a thermal coupling of the heat sink composed of metal plates, it is sufficient for there to be a large-area contact between a bottom metal plate and the rod.

### BRIEF DESCRIPTION OF DRAWINGS

Other features and advantages of the embodiments according to the invention will be explained in greater detail below with reference to exemplary embodiments and based on the drawings. In the schematic depictions in the drawings:

FIG. 1: shows a perspective view of two solar modules, which are mechanically secured to each other at an adjoining edge region;

FIG. 2: shows a perspective view of two progressively cut-away solar modules from the same point of view as FIG. 1;

FIG. 3: shows a perspective view of a first metal plate of a heat sink;

FIGS. 4a-4c: show partially cut-away views of the metal plate from FIG. 3;

FIG. 5: shows a perspective view of a stack of metal plates with a serially repeating mirror-image orientation;

FIG. 6: shows a side view of the arrangement from FIG. 5, and

FIG. 7: shows a perspective view of stacks of metal plates according to FIG. 5 secured in corresponding recesses of a chassis of a solar module according to FIG. 1.

### DETAILED DESCRIPTION OF THE INVENTION

The same reference symbols are consistently used for the same elements throughout the various drawings. Without limiting the invention, all that is shown and described below is a use of heat sinks in flat and highly mechanically resilient solar modules with a regular hexagonal-edged shape, which serve as a replacement for a pavement and can therefore also be driven over by heavy trucks. These solar modules are arranged adjacent to one another on a generally not completely flat surface. However, it is clearly evident to the person skilled in the art that an adaptation to supporting surfaces of any three-dimensional shape is also possible in the same way by using triangular elements in the manner of a finite element mesh with corresponding adaptation of the heat sinks in order to achieve an overlap with a predetermined surface shape. The elements or modules themselves can also have a non-planar surface through a corresponding adaptation of the heat sinks contained therein.

As electronic components arranged in a closed housing, solar modules pose a particular technical challenge in thermal terms when used as a pavement especially since active cooling over the length of a pavement would be too costly and unreliable. This type of solar module can also only be arranged at a static angle and generally does not allow any rear ventilation for heat dissipation. However, effective heat dissipation increases the efficiency of solar cells and also extends the average service life of electronic components. This important task is performed by the heat sinks described below.

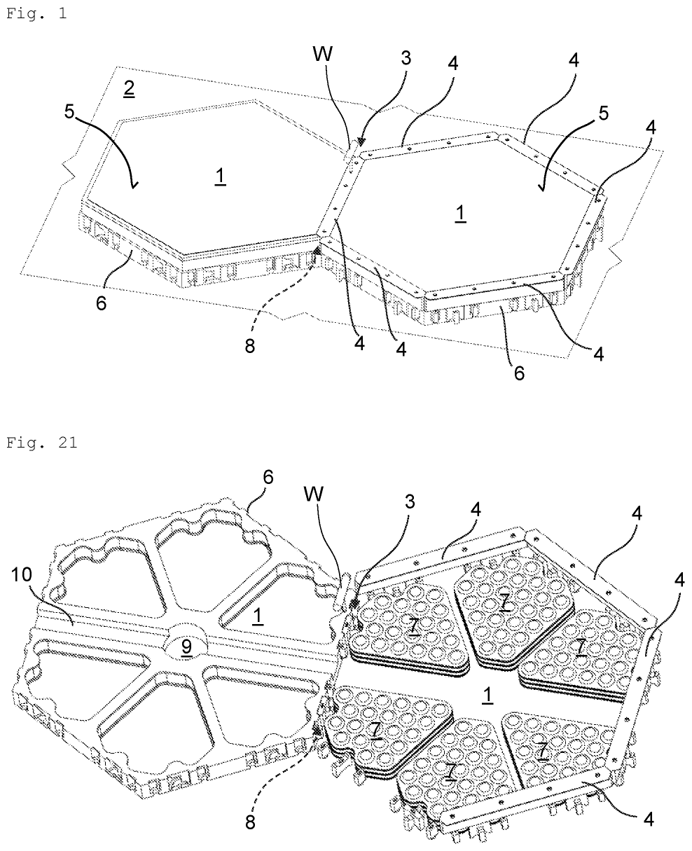

FIG. 1 shows a perspective view of two solar modules 1 with an approximately hexagonal basic structure, which are arranged on a supporting surface 2 and mechanically secured together at an adjoining edge region 3 by means of various connecting devices, which can be opened and closed by means of a tool W. The connecting devices are covered by covering strips 4 as protection against environmental influences. Underneath a highly mechanically resilient surface 5 made of glass as a covering layer, solar cells that are not shown in detail are accommodated along with electronics, heating pads for electrically heating modules 1 in case of snow and ice, and sensors for pressure and temperature, etc. as well as LED modules, which are all supplied with electrical current by the solar cells and are connected via lines to adjacent solar modules 1 in order to exchange electrical energy and information.

The surface 5 facing the sun is adjoined by a chassis 6 with a frame structure. The chassis 6 is made of an elastomer or a rubber-elastic plastic in order to be able to compensate for irregularities in the supporting surface 2. In order to be able to dissipate a powerful force from the surface 5 through the solar module 1 into the supporting surface 2, heat sinks 7 are positioned directly behind the solar modules, which are not shown in detail, and thus on a side of the surface 5 facing away from the sun that is in thermal contact with the solar cells. In this exemplary embodiment, each solar module 1 is provided with six heat sinks 7, which are embodied as segments that are separated from one another by the frame structure of the chassis 6. FIG. 2 shows a perspective progressively cut-away view of two solar modules 1 from the same point of view as FIG. 1.

In addition to the surface 5 with the solar cells serving as a covering layer, in two edge regions 3, covering lips 4 made of an elastomer material have been removed, which together with the covering layers 5 precisely fill and seal a channel 8 between these covering layers 5 of adjacent modules 1. The module 1 on the left in FIG. 2 has been reduced to the chassis 6, whose edge regions 3 are provided with connecting devices for mechanically coupling to adjoining modules 1. In the frame-like structure of the chassis 6, a central receptacle 9 is provided among other things for a set of data-processing electronics, which in a real use is connected to adjoining modules 1 via a channel 10 for power and data lines.

All other components have been removed from the module 1 on the right in FIG. 2 except for the securing elements of the respective connecting devices, the heat sinks 7 that are coupled in a thermally optimized way, and four of the six covering lips 4 that are inserted to protect the underlying connecting devices from contamination. The heat sinks 7 in the form of the six segments cover a significant part of the area above the supporting surface 2 and thus support the covering layer 5 of the solar module 1 while conveying mechanical loads into the supporting surface 2.

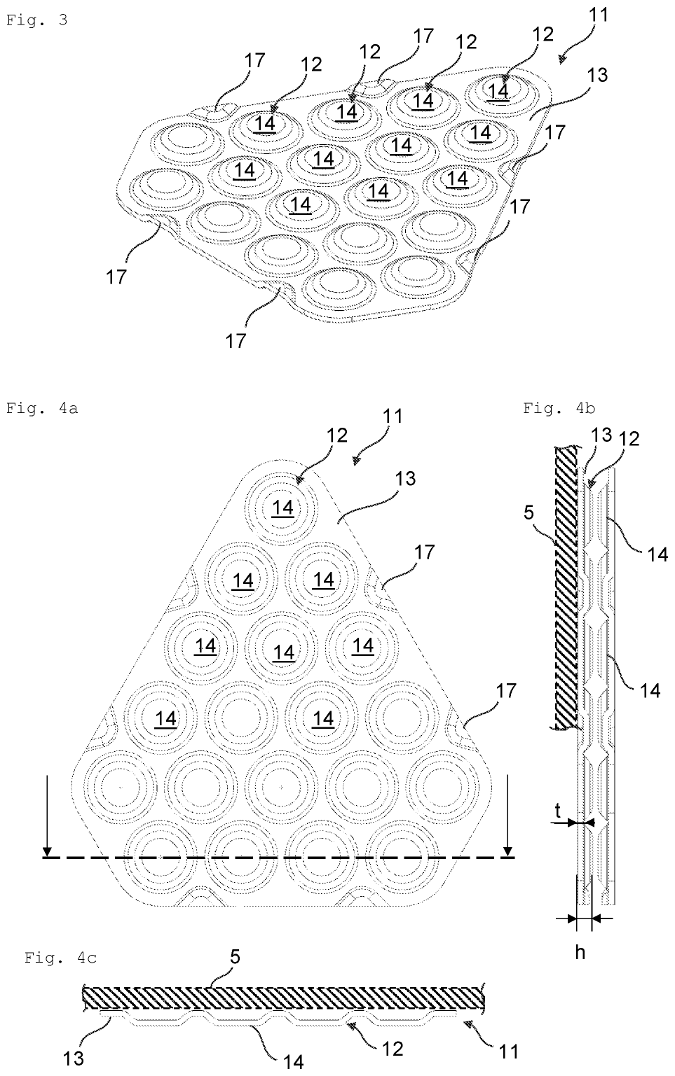

FIG. 3 shows a perspective view of a first metal plate 11 of a heat sink 7. The metal plate 11 is embodied as an aluminum sheet and has a stamped three-dimensional structure auf. This three-dimensional structure has regularly distributed beads or nubs 12, which extend from a flat or planar base 13 to raised areas or apexes 14 with flattened plateau surfaces.

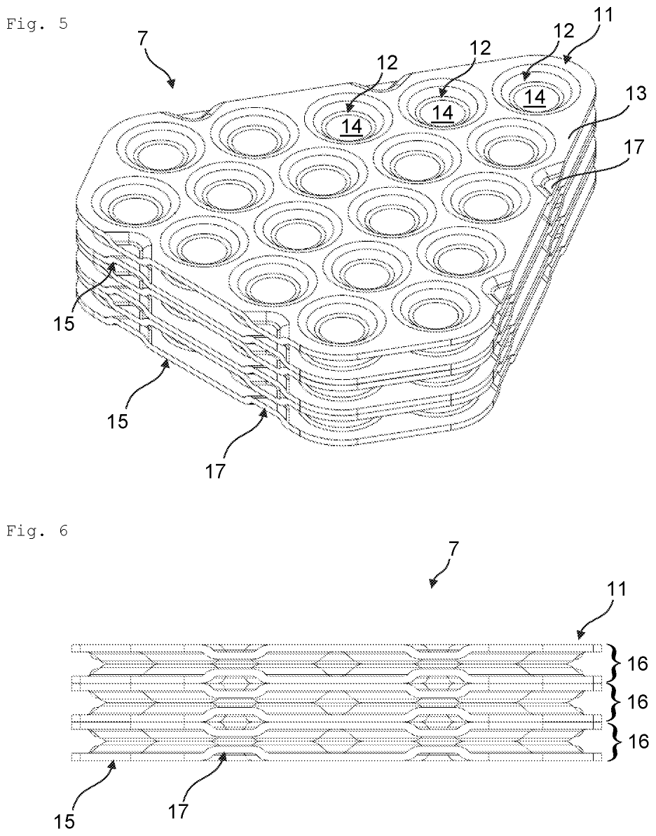

The drawings in FIGS. 4a-4c show partially cut-away views of the metal plate 11 from FIG. 3. In this case, a stamping of an aluminum sheet with an area of approx. 400 cm² has produced an area of approx. 120 cm² of the flat base 13 and an area of approx. 65 cm² of all of the plateau apexes 14. The three-dimensional structure shown is embodied in an optimized way to support high static and dynamic mechanical loads and is embodied as a regular three-dimensional structure. In the present exemplary embodiment, the aluminum sheet measures approximately t=3.175 mm at every point at a height h of approximately 8.47 mm of the metal plate 11 that is provided with nubs 12. This results in nubs 12 with linear flanks that protrude by at most approx. 5.29 mm from the flat base 13 adjoined by transition radii at an angle of approx. 40°. FIG. 4b shows a positioning of a first metal plate 11 of a heat sink 7 with a first metal plate 11 that contacts the surface 5 with the solar cells contained therein and a second metal plate 15 adjoining this first metal plate 11 and embodied as mirror-symmetrical to it.

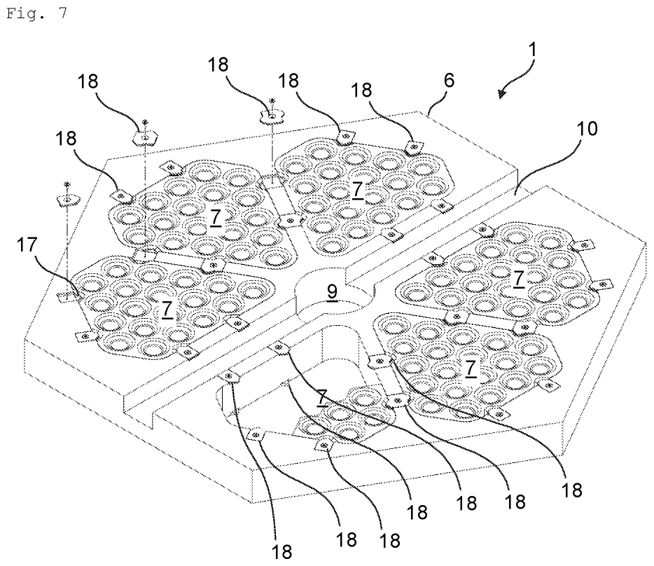

FIG. 5 shows a perspective view of a stack of metal plates, wherein each first metal plate 11 and a second metal plate 15 oriented relative thereto in mirror-image fashion are positioned so they are stacked on top of each other as a packet 16. Advantageously, the metal plate 15 in this exemplary embodiment is embodied as completely symmetrical so that only a single geometry has to be provided by only one mold to produce the metal plates 11, 15. The first metal plate 11 and the second metal plate 15 thus differ only with regard to their orientation during assembly. Following the pattern indicated in FIG. 5, three packets 16 are provided to form a heat sink 7. It is clear that the second metal plate 15 likewise has a three-dimensional profile and is provided with the same three-dimensional structure as the first metal plate 11. Each packet 16 thus comprises two metal plates 11, 15 that are stacked on top of each other, are not secured to each other, and are positioned so that they conform to each other in terms of their contour.

FIG. 6 is a side view of the arrangement from FIG. 5 composed of three packets 16, each having a first metal plate 11 and a second metal plate 15 oriented in mirror-image fashion thereto. With a high heat dissipation capacity and a total height of approx. 5.1 cm, this arrangement is significantly lighter than a solid block of aluminum.

FIG. 7 is a perspective view of heat sinks 7 embodied as respective stacks of metal plates loosely stacked on top of one another according to FIG. 5 secured in corresponding recesses of the chassis 6 of a solar module 1 according to FIGS. 1 and 2. In this case, recessed regions 17 are provided at the edges of the metal plates 11, 15 in order to secure the heat sink 7 to the chassis 6 by means of plastic retaining arms 18 of two different designs that are screwed to both surfaces of the chassis 6. In this case, these recessed regions 17 are to be provided only on a bottom sheet metal plate and a top sheet metal plate 11, 15 for the purpose of securing them in this external frame, which in this case is formed by the chassis 6 and otherwise by a housing part of a module 1.

The heat sinks 7, which are composed of stacked beaded aluminum sheets, serve on the one hand to dissipate heat from a set of electronics positioned in a large area overlying this and thus increase an efficiency, in particular of solar cells. In addition, by dissipating heat from powerfully heated components or regions of the electronics, the heat sinks 7 reduce a tendency for hot spots to form. This increases an average service life of electronic components due to a rapid increase in the probability of failure associated with the temperature without the electronic components used having to be intentionally oversized in order to take into account the higher temperatures in the event of high loads. It is also unnecessary to provide any redundancy of components, allowing savings to be achieved not only with regard to costs, but also with regard to installation space. Another function of the above-described heat sinks 7 is that they are very pressure-stable and are thus able to withstand powerful loads due to contact forces. When subjected to a load, for example due to a vehicle rolling over the solar modules, the highly mechanically resilient protective layer, together with underlying functional elements, is supported on the heat sinks 7 instead of the respective chassis 12 for the dissipation into the supporting surface 2. With an area of the highly mechanically resilient surface 5 of approx. 0.24 m², an impinging weight, for example of a heavy vehicle, over six heat sinks 7 with an almost identical total area is dissipated into the supporting surface 2.

In an exemplary embodiment not shown in detail in the drawings, a stack composed of three packets 16 of first metal plates 11 and second metal plates 15 arranged in pairs is provided, which, on the side of the stack of metal plates opposite from the closed housing of the electronic component or circuit of the solar module 2, has a dissipation of heat into the supporting surface 2 in the form of a heat-conducting rod, for example made of aluminum.

1. A heat sink on a closed housing of an electronic component or circuit,
comprising:
a cooling element positioned on a back side of the electronic component or circuit with a thermal coupling, wherein the cooling element comprises at least one first metal plate with a three-dimensional structure, wherein heat is introduced via a flat base of the at least one first metal plate and the heat is conveyed away from the flat base toward apexes of the three-dimensional structure, and at least one second metal plate is positioned so that the at least one second metal plate adjoins the at least one first metal plate or the apexes of the at least one first metal plate with thermal contact in order to convey the heat away from the flat base.

2. The heat sink according to claim 1, wherein the at least one first metal plate and the at least one second metal plate is each embodied as an aluminum sheet with a stamped three-dimensional structure with beads or nubs.

3. The heat sink according to claim 2, wherein the three-dimensional structure is embodied in an optimized way to support high static and dynamic mechanical loads.

4. The heat sink according to claim 2, wherein the three-dimensional structure is embodied as a regular structure.

5. The heat sink according to claim 2, wherein the at least one second metal plate likewise has a three-dimensional profile.

6. The heat sink according to claim 1, wherein the heat sink is shaped in such a way that a base of the at least one first metal plate and a base of the at least one second metal plate are oriented facing in opposite directions from each other.

7. The heat sink according to claim 1, wherein a mirror-image arrangement of the at least one first metal plate and the at least one second metal plate with respect to each other is provided, with both the at least one first metal plate and the at least one second metal plate having the same profiling.

8. The heat sink according to claim 7, wherein the at least one first metal plate and the at least one second metal plate are stacked on top of each other as a packet and are not secured to each other.

9. The heat sink according to claim 7, wherein recessed regions are provided at edges of the at least one first metal plate and the at least one second metal plate in order to secure the heat sink.

10. The heat sink according to claim 8, comprising a stack composed of three packets of the first metal plates and the second metal plates arranged in pairs, wherein the stack dissipates heat into a supporting surface through a rod.

11. The heat sink according to claim 5, wherein the three-dimensional profile of the at least one second metal plate has the same three-dimensional structure as the at least one first metal plate.

12. The heat sink according to claim 9, wherein the recessed regions are provided only on a respective bottom and top of the at least one first metal plate and the at least one second metal plate for securing the heat sink in an external frame, which is formed by a chassis or housing part of a module.

13. The heat sink according to claim 10, wherein the stack dissipates heat into the supporting surface from a side of the stack of metal plates opposite from the closed housing of the electronic component or circuit of a solar module.
